(19) United States
(12) Patent Application Publication
(10) Pub. No.: US 2013/0342983 A1
(43) Pub. Date: Dec. 26, 2013

(54) ELECTRONIC DEVICE AND EXPANSION CARD OF THE SAME

(71) Applicants: JUN-HUI WANG, Shenzhen City (CN); YU HAN, Shenzhen City (CN); ZHENG-HENG SUN, Tu-Cheng (TW)

(72) Inventors: JUN-HUI WANG, Shenzhen City (CN); YU HAN, Shenzhen City (CN); ZHENG-HENG SUN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/556,227

(22) Filed: Jul. 24, 2012

(30) Foreign Application Priority Data
Jun. 20, 2012 (CN) 2012102047982

(51) Int. Cl. H05K 1/18; G06F 1/16

(52) U.S. Cl. 361/679.02; 361/748

(57) ABSTRACT

An electronic device includes an enclosure with a bottom wall and a sidewall, a motherboard mounted on the bottom wall, an expansion card, and an expansion unit. The sidewall defines a first opening and a second opening. The expansion card includes an edge connector, a number of first sockets exposed through the first opening, and an expansion socket unit. The expansion socket unit includes a second socket. The expansion unit includes an expansion socket exposed through the second opening. The expansion socket of the expansion unit is electrically connected to the second socket by cables.

### BACKGROUND

1. Technical Field

The disclosure relates to electronic devices and, more particularly, to an electronic device having expansion cards.

2. Description of Related Art

Electronic devices, such as servers, need more and more expansion cards to expand functions. However, there is not enough room with the traditional layout of expansion cards to provide enough interfaces to satisfy the increased needs.

### BRIEF DESCRIPTION OF THE DRAWINGS

Many aspects of the present embodiments can be better understood with reference to the following drawing. The components in the drawing are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an embodiment of an electronic device.

FIG. 2 is an assembled, isometric view of FIG. 1.

### DETAILED DESCRIPTION

The disclosure, including the accompanying drawings, is illustrated by way of examples and not by way of limitation. It should be noted that references to “an” or “one” embodiment in this disclosure are not necessarily to the same embodiment, and such references mean at least one.

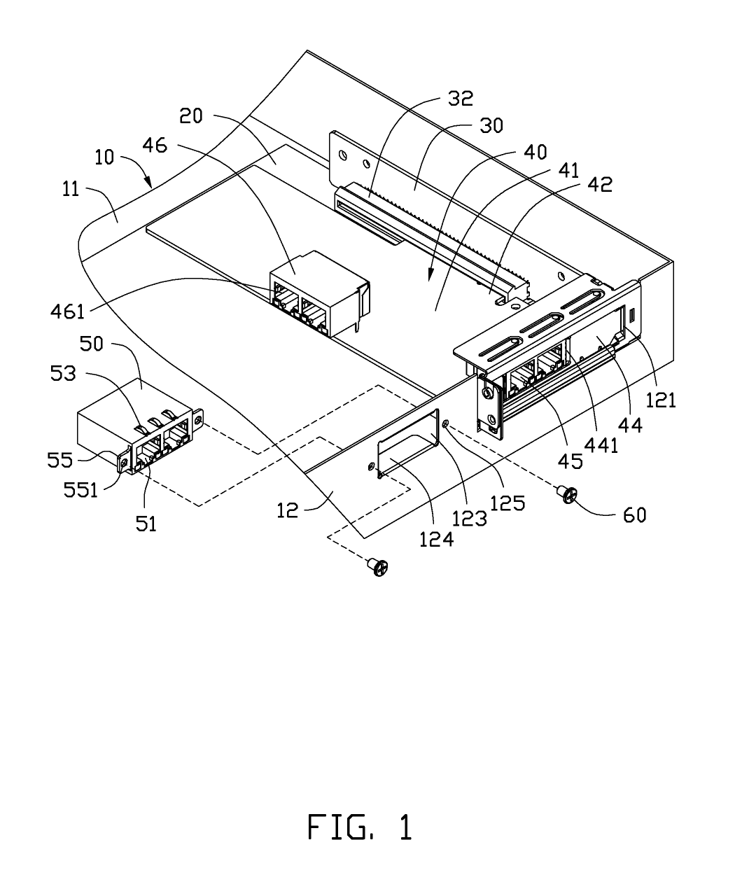

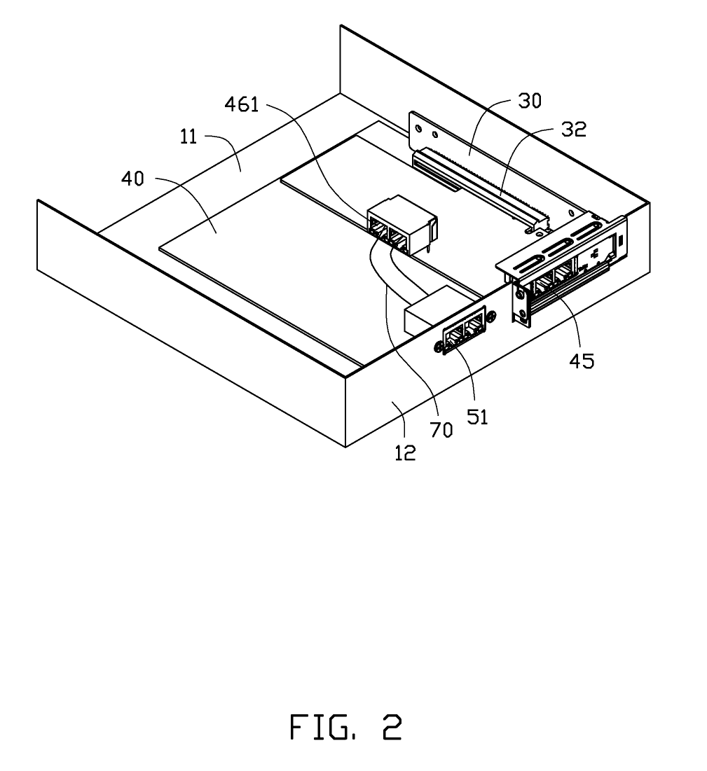

Referring to FIGS. 1 and 2, an exemplary embodiment of an electronic device includes an enclosure 10, a motherboard 20, a conversion card 30, an expansion card 40, and an expansion unit 50.

The enclosure 10 includes a bottom wall 11 and a sidewall 12 extending up from one side of the bottom wall 11. The sidewall 12 defines a first opening 121 and a second opening 123 adjacent to the first opening 121. Two tabs 124 extend inward from the sidewall 12 and are located above and below the second opening 123 respectively. Two through holes 125 are defined in the sidewall 12, at opposite sides of the second opening 123 respectively.

The motherboard 20 is supported on the bottom wall 11. The conversion card 30 is electrically connected to the motherboard 20 and perpendicular to the motherboard 20. A socket 32 is arranged on the conversion card 30 and parallel to the motherboard 20.

The expansion card 40 includes a printed circuit board 41, an edge connector 42 set on a first side of the printed circuit board 41, a plurality of first sockets 45 set on an end of the printed circuit board 41 and electrically connected to the printed circuit board 41, and an expansion socket unit 46 set on a second side of the expansion card 40 opposite to the first side and electrically connected to the printed circuit board 41. A blocking piece 44 is fixed to the sidewall 12 and defines a plurality of through holes 441. The first sockets 45 are assembled to the blocking piece 44 and exposed through the corresponding through holes 441. The expansion socket unit 46 includes two second sockets 461.

The expansion unit 50 includes two expansion sockets 51. A plurality of resilient pieces 53 are set on a top surface of the expansion unit 50. Two mounting pieces 55 perpendicularly extend from opposite ends of the expansion unit 50. Each mounting piece 55 defines a mounting hole 551.

The expansion unit 50 is located between the tabs 124, with the expansion sockets 51 aligning with the second opening 123. Two screws 60 extend through the through holes 125 and engage in the mounting holes 551, to fix the expansion unit 50 to the sidewall 12. The resilient pieces 53 abut against one of the tabs 124 above the second opening 123. The expansion sockets 51 are exposed through the second opening 123. The expansion sockets 51 are electrically connected to the second sockets 461 by cables 70. The expansion sockets 51 are used for electrically connecting more peripheral devices.

In the embodiment, the expansion card 40 is a network card. The first sockets 45, the second sockets 461, and the expansion sockets 51 are all registered jack-45 (RJ-45) connectors. The cables 70 are network cables. The expansion sockets 51 are connected to the second sockets 461 pin to pin.

In the embodiment, the expansion card 40 is connected to the motherboard 20 through the conversion card 30. In another embodiment, the expansion card 40 can be directly connected to the motherboard 20.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. An expansion card, comprising:
a printed circuit board;
an edge connector set on a first side of the printed circuit board;
a plurality of first sockets set on an end of the printed circuit board and electrically connected to the printed circuit board; and
an expansion socket unit set on a second side of the expansion card opposite to the first side, wherein the expansion socket unit is electrically connected to the printed circuit board, and includes a second socket.

2. The expansion card of claim 1, wherein the expansion card is a network card.

3. The expansion card of claim 2, wherein the first sockets and the second socket are registered jack-45 (RJ-45) connectors.

4. An electronic device, comprising:
an enclosure comprising a bottom wall and a sidewall extending from a side of the bottom wall, wherein the sidewall defines a first opening and a second opening;
a motherboard mounted on the bottom wall;
an expansion card comprising a printed circuit board, an edge connector electrically connected to the motherboard, a plurality of first sockets set on the printed circuit board and exposed through the first opening, and an expansion socket unit set on a side of the printed circuit board and comprising a second socket; and
an expansion unit comprising an expansion socket exposed through the second opening, wherein the expansion socket is electronically connected to the second socket through cables.

5. The electronic device of claim 4, wherein the expansion card is a network card.

6. The electronic device of claim 5, wherein the first sockets, the second socket, and the expansion socket are registered jack-45 (RJ-45) connectors.

7. The electronic device of claim 4, wherein the expansion socket is connected to the second socket by pin to pin.

8. The electronic device of claim 4, further comprising a conversion card perpendicularly and electrically connected to the motherboard, wherein the conversion card comprises a socket in which the edge connector is plugged.

9. The electronic device of claim 4, wherein two tabs extend inward from the sidewall and located above and below the second opening respectively, the expansion unit is located between the tabs, the expansion socket aligns with the second opening.

10. The electronic device of claim 9, wherein a plurality of resilient pieces is formed on a top side of the expansion unit and abutting against one of the tabs above the second opening.

11. The electronic device of claim 9, wherein two through holes are defined in the sidewall and at opposite sides of the second opening respectively, two mounting pieces extend from opposite ends of the expansion unit, each mounting piece defines a mounting hole, two screws extend through the through holes and engage in the mounting holes.
